(19) United States
(12) Patent Application Publication
(10) Pub. No.: US 2023/0335659 A1
(43) Pub. Date: Oct. 19, 2023

(54) ENHANCED PHOTOVOLTAIC CELL ASSEMBLY

(71) Applicant: Sergio Walter Weffer, Salt Lake City, UT (US)

(72) Inventor: Sergio Walter Weffer, Salt Lake City, UT (US)

(21) Appl. No.: 18/301,902

(22) Filed: Apr. 17, 2023

Related U.S. Application Data
(60) Provisional application No. 63/363,075, filed on Apr. 15, 2022.

(51) Int. Cl. H01L 31/054; H01L 31/0475

(52) U.S. Cl. CPC H01L 31/0543; H01L 31/0475; H01L 31/05

(57) ABSTRACT

A photovoltaic cell assembly positions lenses within a cell chamber lined with photovoltaic cells in an effort to foster multiple strikes of photons from a same beam of light onto different cells, thereby multiplying incidences of the photovoltaic effect and increasing the efficiency of power generation by the assembly.

### CROSS-REFERENCES TO RELATED APPLICATIONS

The present invention claims priority under 35 USC § 119(e)(3) to prior filed U.S. Application No. 63/363,075, filed on Friday, Apr. 15, 2022, and incorporates the same by reference herein in its entirety.

### FIELD OF THE INVENTION

The present invention relates to the field of solar power generation and more particularly relates to a solar array of photovoltaic cells combined with lenses to increase power generation from a given quantity of light.

### BACKGROUND OF THE INVENTION

Solar power is one hope for the world's energy needs. As more and more solar power is used, a corresponding lesser amount of power from fossil fuels is required. Solar panels are a collection of solar modules which are in turn made of collection of photovoltaic cells which are interconnected in series. This is done to achieve a desired voltage output. Parallel connections of larger modules are then used to increase the output current. Each photovoltaic cell is, ideally, struck by radiant solar energy and creates a small current through the photovoltaic effect. As a light photon strikes an electron in the material, the electron is excited into a free conductive state. Enough of these electrons then can create a respectable electrical current.

However, solar panels are notoriously inefficient when looking at their ability to convert solar energy into usable power, with the most efficient panels currently achieving less than 25% efficiency. This means that 75% or more of solar energy that strikes a solar panel is reflected off the panel with no power generated therefrom. What is needed then, is a way to increase the conversion efficiency of solar panels.

The present invention is a device which will capture reflected solar energy and have the same beam of light strike multiple photovoltaic cells before exiting a chamber. This construction then would generate more power than traditional methods as the same cells could be used to generate multiple hits from the beam of light, rather than just one. The present invention represents a departure from the prior art in that the photovoltaic cell assembly of the present invention allows for the use of lenses to bend light into a chamber lined with photovoltaic cells to accomplish multiple strikes and incidences of the photovoltaic effect.

### SUMMARY OF THE INVENTION

In view of the foregoing disadvantages inherent in the known types of solar arrays, an improved solar cell configuration is presented. The invention may provide a configuration of lenses and cells that meets the following objectives: that the assembly would generate multiple hits on photovoltaic cells from a singular beam of light, that it be simple to implement, that it be cost effective and use familiar materials. As such, a new and improved photovoltaic cell assembly may comprise a plurality of cells having cell walls lined with photovoltaic cells and at least one lens residing within each cell to bend incident light into the cell and direct incoming light beams onto multiple internal walls of the cell before reflecting out of said cell to accomplish these objectives.

The more important features of the invention have thus been outlined in order that the more detailed description that follows may be better understood and in order that the present contribution to the art may better be appreciated. Additional features of the invention will be described hereinafter and will form the subject matter of the claims that follow.

Many objects of this invention will appear from the following description and appended claims, reference being made to the accompanying drawings forming a part of this specification wherein like reference characters designate corresponding parts in the several views.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also, it is to be understood that the phraseology and terminology employed herein are for description and should not be regarded as limiting.

As such, those skilled in the art will appreciate that the conception, upon which this disclosure is based, may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

To describe the way the above-recited and other advantages and features of the invention can be obtained, a more particular description of the invention briefly described above will be rendered by reference to specific example embodiments thereof which are illustrated in the appended drawings. Understanding that these drawings depict only typical embodiments of the invention and are therefore not to be considered as limiting of its scope, the invention will be described and explained with additional specificity and detail using the accompanying drawings.

FIG. 1 is a top schematic view of a module of photovoltaic cell chambers assembled to form a solar array according to the present invention.

FIG. 2 is a schematic view of a single cell chamber.

FIG. 3 is a schematic view of an alternate single cell chamber.

### DESCRIPTION

With reference now to the drawings, a preferred embodiment of the improved photovoltaic cell assembly is herein described. It should be noted that the articles “a”, “an”, and “the”, as used in this specification, include plural referents unless the content clearly dictates otherwise.

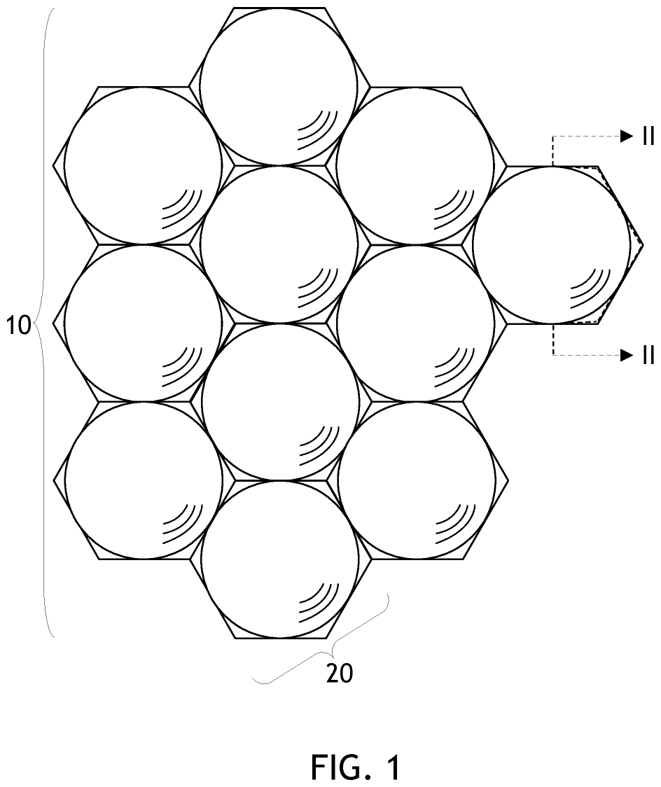

With reference to FIG. 1, a plurality of solar cell assemblies 20 are configured into a module of assemblies 10. Each solar cell assembly 20 is situated within a hexagonal cell, which are then positioned adjacent to each other. Hexagonal cells are preferred as they are geometrically easy to construct, and they associate with one another in a very efficient use of space. Other shapes may be used but are not as preferred. The assemblies contain photovoltaic cells which are then interconnected according to the desired design of the entire array.

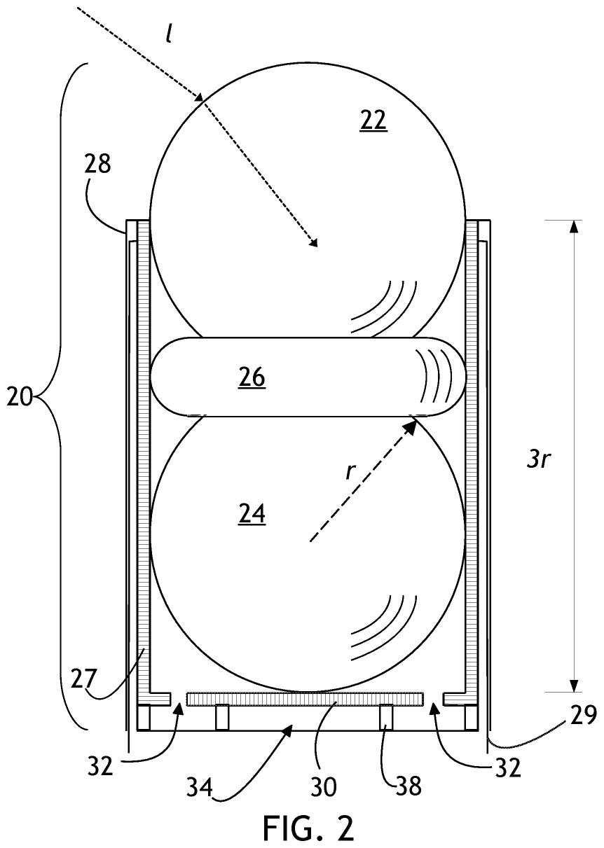

With reference to FIG. 2, solar cell assembly 20 is contained within assembly walls 28. These assembly walls 28 define an internal volume and provide support for internally mounted photovoltaic cells 27. Each wall 28 supports at least one photovoltaic cell 27, so the internal volume is a solar collection chamber. Electrical connection 29 runs within the walls to connect each assembly into a functioning solar array. In one embodiment, three lens structures are contained within the defined volume and form the equivalent of a compound lens in solar cell assembly 20: an upper spherical lens 22 stacked upon a lower spherical lens 24, and a central toroidal lens 26 therebetween. When light l strikes the upper spherical lens 22, it is refracted towards the center of the lens and into the cell structure 20. From there, it may pass through lens 22 and strike a photovoltaic cell 27 on a wall 28 or may pass into one of the other lenses 24, 26. Eventually, light will leave the lenses and strike photovoltaic cells 27 one of the walls 28. At this point, light will re-enter a lens and be refracted again. A good portion of light will then escape, but some will strike another photovoltaic cell 27 before ultimately escaping solar cell assembly 20. These multiple contacts will multiply the energy created from the solar cell assembly 20 over a traditional flat panel arrangement. Lenses should contact opposed walls 28 of the solar collection chamber and should occupy a majority of the defined space.

As the solar cell assembly 20 is inherently recessed, and will often be parallel to the ground, a water control system should be provided to handle any precipitation or condensation which may otherwise collect inside the cell assembly 20. A simple and effective drainage system may be employed by providing a lower drainage chamber 34 beneath floor 30 of the solar cell assembly 20. Drainage holes 32 provide egress for any collected liquids. The walls 28 of the solar cell assembly could then be supported by spot supports 38 under the corners of the walls 28, or larger support walls, so long as the drainage chamber remains open for fluid communication to the eventual drain.

The lenses may be made of any refractive and durable material, with glass and polymers being preferred. Ideally, half of the upper lens 22 should extend out of the cell assembly 20 and act as a capturing device for ambient light. The resulting dimensions of the cell would have an internal, wall-to-opposed wall width of 2r and a height of 3 r. The toroidal lens 26 nests between the upper lens 22 and lower lens 24. This torus will have a major radius of r and a minor radius made to fit within the confines of the spherical lenses 22, 24 and cell walls 28, about 0.25 r.

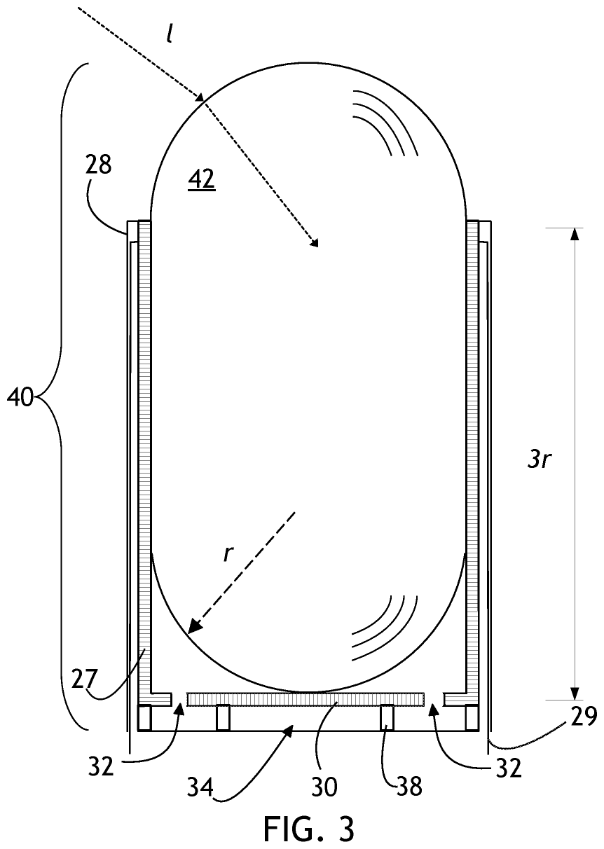

In an alternate embodiment, the three lens structures 22, 24, 26 may be replaced by a single lens 42, shown in FIG. 3. This single lens 42 may best be described as “pill-shaped” having a main cylindrical body with a radius or r and two semi-spherical ends, each also with a radius of r, yielding an overall length of 4 r. This alternate solar cell 40 is but one example of alternate designs. What is critical is that the initial exterior lens 42, 22 in whatever embodiment used will bend incident light into the solar cell assembly 20 so that the light may strike the photovoltaic cells 27 lining the assembly walls 28. In this way, light will be reflected for multiple strikes within the chamber itself until the light exits the chamber through the exterior lens. Other than this requirement, and while the disclosed embodiments are preferred, the lens shape, size, and design, be it a single simple lens of FIG. 3 or a compound lens of FIG. 2, is variable and determined by the designer for effectiveness and other concerns such as ease of manufacture and available materials.

Although the present invention has been described with reference to preferred embodiments, numerous modifications and variations can be made and still the result will come within the scope of the invention. The described embodiments are to be considered in all respects only as illustrative and not restrictive. No limitation with respect to the specific embodiments disclosed herein is intended or should be inferred. Therefore, the scope of the invention is indicated by the appended claims rather than by the foregoing description. All changes which come within the meaning and range of equivalency of the claims are to be embraced within their scope.

What is claimed is:

1. A solar array comprising a plurality of solar cell assemblies, each solar cell assembly in interoperable connection to allow for electricity generation and collection from said solar cell assemblies and each solar cell assembly further comprising:
a plurality of assembly walls defining a solar collection chamber;
at least one photovoltaic cell mounted upon each of the plurality of walls;
at least one lens resident inside the solar collection chamber and occupying at least a majority of a volume therein.

2. The solar array of claim 1, the at least one lens of at least one solar cell assembly being two stacked spherical lenses and one toroidal lens located therebetween, the lenses having sufficient radii to contact opposed walls of the solar cell assembly.

3. The solar array of claim 1, the at least one lens of at least one solar cell assembly being pill-shaped with a diameter to fit within and contact opposed sides of the solar cell assembly.

4. The solar array of claim 1, each solar cell assembly further comprising a lower floor with at least one drain.

5. The solar array of claim 1, the at least one lens of at least one solar cell assembly extending above a rim defined by the solar cell assembly walls.
